(19) United States
(12) Patent Application Publication
(10) Pub. No.: US 2017/0162732 A1
(43) Pub. Date: Jun. 8, 2017

(54) ARRANGEMENT FOR A THIN-FILM PHOTOVOLTAIC CELL STACK AND ASSOCIATED FABRICATION METHOD

(71) Applicant: COMMISSARIAT A L'ENERGIE ATOMIQUE ET AUX ENERGIES ALTERNATIVES, Paris (FR)

(72) Inventors: Louis GRENET, GRENOBLE (FR); Olivier DELLEA, LA TALAUDIERE (FR); Fabrice EMIEUX, VOREPPE (FR)

(21) Appl. No.: 15/364,023

(22) Filed: Nov. 29, 2016

(30) Foreign Application Priority Data
Dec. 2, 2015 (FR) 1561713

(51) Int. Cl. H01L 31/032; H01L 31/18; H01L 31/0232; H01L 31/0468; H01L 31/0216

(52) U.S. Cl. CPC H01L 31/0324; H01L 31/0468; H01L 31/02167; H01L 31/02327; H01L 31/18

(57) ABSTRACT

An arrangement for a thin-film photovoltaic cell stack comprises a substrate layer for a photovoltaic cell and a molybdenum grid positioned on the substrate layer, an ultra-thin alloy layer made of copper, indium, gallium and selenium positioned on the molybdenum grid, and a buffer layer positioned on the ultra-thin alloy layer made of copper, indium, gallium and selenium and a window layer positioned on the buffer layer.

### CROSS-REFERENCE TO RELATED APPLICATIONS

This application claims priority to foreign French patent application No. FR 1561713, filed on Dec. 2, 2015, the disclosure of which is incorporated by reference in its entirety.

### FIELD OF THE INVENTION

The invention relates to an arrangement for a thin-film photovoltaic cell stack and an associated fabrication method.

A photovoltaic cell is an electronic component which, when exposed to light, generates electricity. It may be used alone (calculator, watch, etc.) but, most commonly, the cells are grouped together in modules or photovoltaic panels.

Several families of photovoltaic cells exist, the most common of which are crystalline silicon cells and thin-film cells.

The technologies referred to as thin-film technologies are based on the use of extremely fine layers with a thickness of a few microns and consist of depositing a uniform fine layer, composed of one or more, generally multiple, powdered materials on a substrate (generally made of glass, vitroceramic, metal, plastic, etc.) under vacuum.

Thin-film cells are fabricated by depositing one or more semiconductive and photosensitive layers on a carrier or substrate made of glass, vitroceramic, plastic or steel, etc. This technology allows the cost of fabrication to be decreased. Thin-film cell technology is currently progressing apace.*

Photovoltaic cells whose absorber layer is based on an alloy of copper Cu, indium In, gallium Ga and selenium Se, known by the term CIGS, currently have the best photovoltaic conversion efficiency (21.7%) among thin-film solar cells, as disclosed in the document “Properties of Cu(In,Ga)Se₂ solar cells with new record efficiencies up to 21.7%”, by Jackson P., Hariskos D., Wuerz R., Kiowski O., Bauer A., Friedlmeier T. M., and Powalla M., (2014); Physica Status Solidi (RRL)-Rapid Research Letters, 9999. The general formula for CIGS may therefore be written as CuIn₁₋ₓGaₓS_{2(1-y)}Se_{2y}, where 0≦x≦1 and 0≦y≦1. Generally, x≈0.3 and y=1.

The general structure of such a photovoltaic cell comprises molybdenum Mo, CIGS, cadmium sulphide CdS and a transparent conductive oxide (generally composed of a ZnO/ZnO:Al or ZnO/ITO bilayer). The rarity of indium In may put a brake on large-scale development of this technology.

To confront this problem, it is envisaged to decrease the thickness of the CIGS active layer, as disclosed in the document “Influence of the Cu (In, Ga) Seₑ thickness and Ga grading on solar cell performance” by Lundberg O., Bodeg\dot{a}M., Malmström J., and Stolt L. (2003); Progress in Photovoltaics: Research and Applications, 11(2), 77-88.

Once the thickness of the CIGS active layer has been decreased, the carrier recombinations on the rear face become sensitive and substantially decrease the open-circuit voltage Voc of the solar cell.

Efforts have shown that introducing, for example, a layer of aluminium between the Mo and the CIGS with localized holes makes it possible to decrease these recombinations and to increase the Voc, as disclosed in the document “Employing Si solar cell technology to increase efficiency of ultra-thin Cu(In, Ga)Se₂ solar cells” by Vermang B., Wätjen J. T., Fjällström V., Rostvall F., Edoff M., Kotipalli R., and Flandre D. (2014); Progress in Photovoltaics: Research and Applications, 22(10), 1023-1029. This document discloses a method for depositing a dielectric layer between the Mo and the CIGS and for locally making openings therein by virtue of a prior deposition of beads or microspheres of cadmium sulphide CdS followed by unsticking/pulling off, or by virtue of optical lithography.

Of course, this also applies to an active layer based on an alloy of copper Cu, zinc Zn, tin Sn, and selenium Se and/or sulphur S, known by the term CZTS, whose general formula may therefore be written as Cu₂ZnSnS_{4(1-y)}Se_{4y}, where 0≦y≦1.

### SUMMARY OF THE INVENTION

An aim of the invention is to overcome the aforementioned problems, and, in particular, to limit the areas of direct electrical contact between the CIGS or CZTS alloy and the molybdenum Mo in order to limit losses due to recombinations on the rear face.

According to one aspect of the invention, an arrangement for a thin-film photovoltaic cell stack is proposed, comprising a substrate layer for a photovoltaic cell and a molybdenum grid or discontinuous molybdenum layer positioned on the substrate layer, an ultra-thin light absorber layer covering the molybdenum grid and filling the holes in the molybdenum grid, and a buffer layer positioned on the ultra-thin light absorber layer and a window layer positioned on the buffer layer.

The molybdenum grid, or, stated otherwise, the discontinuous molybdenum layer, allows the areas of direct electrical contact between the CIGS alloy and the molybdenum Mo to be limited in order to limit losses due to recombinations on the rear face.

An ultra-thin light absorber layer is understood to be a layer whose thickness is between 50 nm and 2.5 μm.

The ultra-thin light absorber layer may be made of CIGS, i.e. an alloy of copper, indium, gallium and selenium.

In one variant, the ultra-thin light absorber layer may be made of CZTS, i.e. an alloy of copper, zinc, tin, and selenium and/or sulphur.

According to one embodiment, the arrangement comprises a dielectric layer positioned between the substrate layer and the molybdenum grid.

The absence of dielectric does away with one deposition step and thus allows the production cost to be decreased. On the other hand, the presence of a suitable dielectric, for example one based on titanium dioxide TiO₂ or alumina Al₂O₃, allows better passivation of the rear contact.

In one embodiment, the arrangement comprises a reflective metal layer positioned between the substrate layer and the dielectric layer.

This fine layer, from a few nanometres to a few hundred nanometres, of a highly reflective metal such as aluminium Al, silver Ag, gold Au, platinum Pt or molybdenum Mo, allows the electrical current flowing through the cell comprising CIGS to be increased. An alternative metal, more reflective than molybdenum Mo, may be used since it is protected in the selenization annealing step by the dielectric layer.

According to another aspect of the invention, a method for fabricating an arrangement for a thin-film photovoltaic cell stack is also proposed, comprising the steps of:

providing a substrate for a photovoltaic cell;

depositing a carpet of microspheres on said substrate;

depositing molybdenum on the carpet of microspheres, a portion of which slips into the interstices separating the microspheres;

removing the microspheres to leave a molybdenum grid;

depositing an ultra-thin light absorber layer on the molybdenum grid; and

depositing a buffer layer and a window layer on the ultra-thin light absorber layer.

The light absorber may be CIGS or CZTS.

In one mode of implementation, the method comprises, in addition, a step of processing the microspheres, after their deposition and before the molybdenum deposition step, modifying the geometry of the microspheres, for example through etching and/or annealing.

Such a step of processing the microspheres allows the geometry of the microspheres, their size and their form, to be modified, and thus makes it possible to manage the sizing of the molybdenum grid when depositing the molybdenum Mo.

According to one mode of implementation, the method comprises, in addition, a step of depositing a dielectric layer on the substrate before the deposition of the microspheres; the dielectric layer then being located between the substrate and the carpet of microspheres.

The absence of dielectric does away with one deposition step and thus allows the production cost to be decreased. On the other hand, the presence of a suitable dielectric, for example one based on titanium dioxide TiO₂ or alumina Al₂O₃, allows better passivation of the rear contact.

In one mode of implementation, the method comprises, in addition, a step of depositing a reflective metal, before the deposition of the dielectric layer; the reflective metal layer then being positioned between the substrate layer and the dielectric layer.

This fine layer, from a few nanometres to a few hundred nanometres, of a highly reflective metal such as aluminium Al, silver Ag, gold Au, platinum Pt or molybdenum Mo, allows the electrical current flowing through the cell comprising CIGS to be increased. An alternative metal, more reflective than molybdenum Mo, may be used since it will be protected in the selenization annealing step by the dielectric layer.

According to one mode of implementation, the deposition of the molybdenum layer on the microspheres is carried out at a thickness of between 100 and 2000 nm, and advantageously at a thickness of substantially 500 nm.

In one mode of implementation, the deposition of the carpet of microspheres implements microspheres of between 100 nm and 5 μm in diameter, and advantageously of substantially 1 μm in diameter.

According to one mode of implementation, the removal of the microspheres implements an ultrasound waterbath lasting between 10 s and 10 min, and advantageously 1 min.

### BRIEF DESCRIPTION OF THE DRAWINGS

The invention will be better understood upon studying a few embodiments described by way of non-limiting examples and illustrated by the appended drawings in which:

FIGS. 1 and 2 schematically illustrate, from the side, arrangements for a thin-film photovoltaic cell stack, according to various aspects of the invention;

FIG. 1a schematically illustrates, from above, the molybdenum grid, according to one aspect of the invention; and

FIG. 3 schematically illustrates the method according to one aspect of the invention.

### DETAILED DESCRIPTION

In the various figures, the elements bearing identical references are identical.

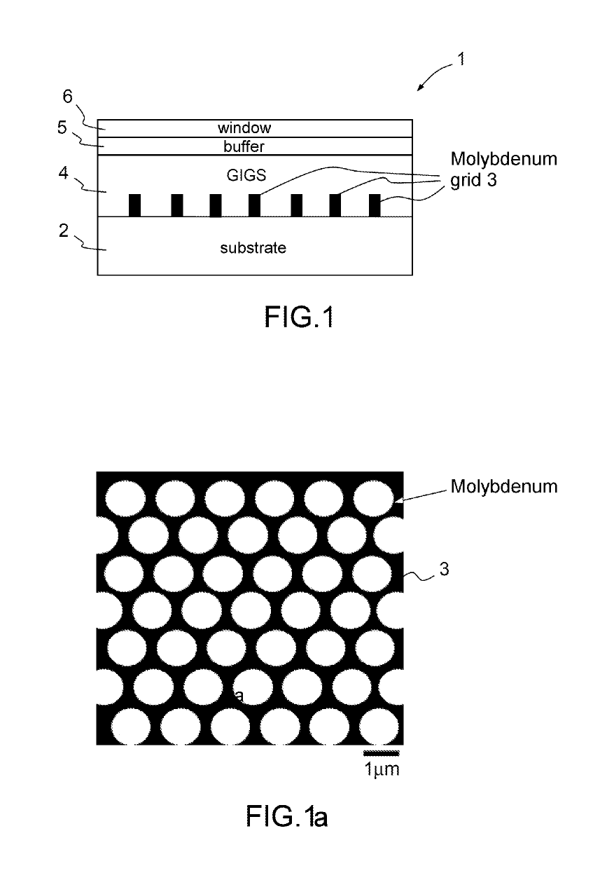

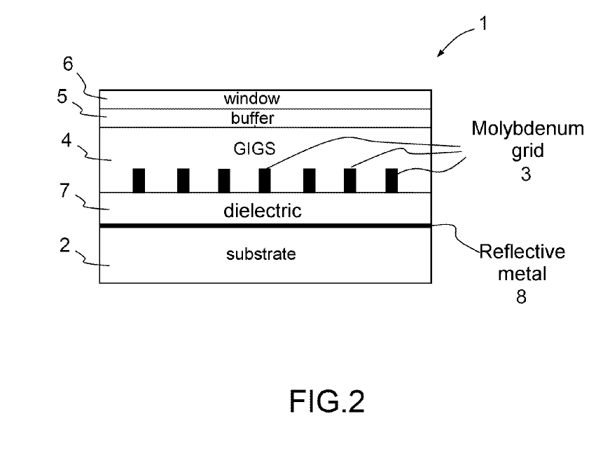

FIG. 1 shows an arrangement 1 for a thin-film photovoltaic cell stack, which comprises a substrate layer 2 for a photovoltaic cell, a molybdenum grid 3 (discontinuous molybdenum layer) positioned on the substrate layer 2, an ultra-thin CIGS alloy absorber layer 4 comprising copper, indium, gallium and selenium positioned on the molybdenum grid, and a buffer layer 5 positioned on the ultra-thin layer 4 and a window layer 6 positioned on the buffer layer 5.

In one variant, the ultra-thin absorber layer may be CZTS, even if the figures and the description represent only the case of the CIGS ultra-thin absorber layer.

The thickness of the CIGS layer 4 is between 50 nm and 2.5 μm, the thickness of the buffer layer 5 is between 10 nm and 200 nm, and the thickness of the window layer 6 is between 50 nm and 500 nm.

FIG. 1a schematically illustrates the molybdenum grid 3 from above, which grid is a discontinuous (presenting holes) layer of Mo, but for which, for any two points defined in the Mo grid, the electrical conductivity between these two points is ensured by the Mo. FIG. 1a schematically shows an exemplary Mo grid from above with circular holes of approximately 1 μm in diameter. The holes are not necessarily circular, or identical or regular. Their characteristic size may vary from a few nanometres to several hundred micrometres and the dimensions along two perpendicular axes in the plane are not necessarily of the same order of magnitude.

FIG. 2 illustrates a variant arrangement 1 for a thin-film photovoltaic cell stack, similar to that of FIG. 1, which comprises an optional dielectric layer 7 positioned between the substrate layer 2 and the molybdenum grid, and an optional reflective metal layer 8 positioned between the substrate layer 2 and the dielectric layer 7.

The dielectric 7 may be based on titanium dioxide TiO₂ or alumina Al₂O₃ allowing better passivation of the rear contact, typically with a thickness of between 1 nm and 1000 nm.

The thickness of the molybdenum Mo grid is between 100 nm and 2 μm.

The fine layer of reflective metal, from a few nanometres to a few hundred nanometres, which may be made of aluminium Al, silver Ag, gold Au, platinum Pt or molybdenum Mo, allows the electrical current flowing through the cell comprising CIGS to be increased. An alternative metal, more reflective than molybdenum Mo, may be used since it will be protected in the selenization annealing step by the dielectric layer.

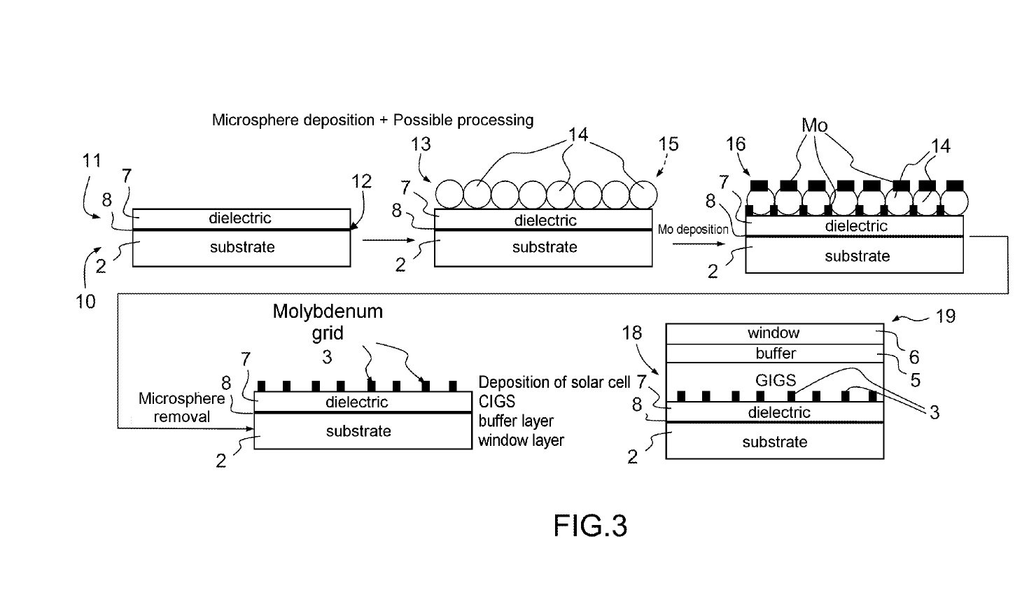

FIG. 3 illustrates the method according to one aspect of the invention.

The method starts with the provision 10 of a substrate 2 for a solar or photovoltaic cell, on which a dielectric 7 is optionally deposited 11 on the upper face of the substrate 2. The substrate 2 is generally a substrate prepared for a solar cell, such as glass or glass with a diffusion barrier, a metal substrate with a diffusion barrier, or a polyimide-based substrate.

The dielectric 7 may be deposited 11 via conventional methods (sputtering, atomic layer deposition (ALD), spin coating, etc.). The thickness of the dielectric 7 is between 1 nm and 1000 nm and is typically 100 nm.

In addition, an optional step of depositing 12 a reflective metal 8, before the deposition 11 of the dielectric layer 7, the reflective metal layer 8 then being positioned between the substrate layer 2 and the dielectric layer 7.

Next, a step of depositing 13 a carpet of microspheres 14 on the dielectric layer 7, or on the substrate 2 in the case that the dielectric 7 is absent, is carried out.

The technique of the roll-to-roll deposition of an ordered film of silica microspheres on a starting substrate by virtue of a technique equivalent to that of Langmuir-Blodgett called Boostream©.

One variant consists of using non-spherical particles: fibre-, disc-, lens-, ring-shaped, etc. The lateral dimensions of the non-spherical particles are similar to those of the spherical particles: advantageously 1 μm, between 100 nm and 5 μm.

The use of non-spherical particles makes it possible to vary the form of the holes in the Mo layer and/or the degree of opening of this Mo layer (form or degree of opening of the grid).

An optional step 15 of processing the microspheres 14 is carried out after their deposition 13 and before the molybdenum Mo deposition step 16, modifying the geometry of the microspheres, for example through reactive ion etching (RIE) or heat treatment.

The molybdenum is deposited both on the microspheres 14 and between their interstices on the dielectric layer 7 or on the substrate 2 in the case that the dielectric 7 is absent.

The thickness of the deposited molybdenum deposit is between 100 nm and 2000 nm, typically 500 nm.

A step 17 of removing the microspheres 14 allows a grid 3 of molybdenum Mo, also called textured molybdenum or structured molybdenum, to be obtained.

Next, an ultra-thin CIGS (an alloy of copper, indium, gallium and selenium) layer is deposited 18 at a thickness of between 50 nm and 2.5 μm, advantageously of 500 nm, via a known method, for example one based on co-evaporation, selenization of precursors deposited under vacuum, selenization of precursors deposited without vacuum, etc.

A thickness of 500 nm is advantageous in that it uses five times less indium than a layer of 2.5 μm.

Methods for producing the CIGS layer are well known to those skilled in the art, and are, for example, described in the document “Handbook of photovoltaic science and engineering”, by Luque, A. and Hegedus, S., published by John Wiley & Sons, in particular on pages 559 to 564.

There exist two main types of deposition methods, the end goal being to obtain a CIGS layer with the following ratios of elements (0.75≦Cu/(In+Ga)≦0.95; 0.55≦In/(In+Ga)≦0.85 and 0.15≦Ga/(In+Ga)≦0.45):

co-evaporation, which consists of simultaneously evaporating the elements copper Cu, indium In, gallium Ga and selenium Se while heating the substrate to 550° C. (450° C.<T<650° C.) in order to obtain the desired material. The evaporation rates of the elements may be constant throughout the process (co-evaporation in one step) or vary in order to obtain composition gradients (co-evaporation in three steps).

selenization of precursors, which consists of depositing precursor layers containing at least copper Cu, indium In and gallium Ga in the following proportions 0.75≦Cu/(In+Ga)≦0.95; 0.55≦In/(In+Ga)≦0.85 and 0.15≦Ga/(In+Ga)≦0.45, via a vacuum deposition method (sputtering, evaporation, etc.) or a method without vacuum (sol-gel, electrodeposition, etc.) at a temperature between room temperature and 600° C., then annealing this precursor layer under an atmosphere containing selenium Se (elementary Se, H₂Se) and potentially sulphur S at a temperature of 550° C. (450° C.<T<650° C.), at a pressure close to atmospheric pressure (0.1° mbar<P<2° bar). The annealing operation is typically of rapid annealing type.

Lastly, a step 19 of depositing a buffer layer 5 (CdS, ZnS, In₂S₃) and a window layer 6 (ZnO/ZnO:Al, ITO, etc.) is carried out in order to obtain a solar cell.

Processes for fabricating a CIGS-based photovoltaic cell are known to those skilled in the art and are described, for example, in the document “Handbook of photovoltaic science and engineering”, by Luque, A. and Hegedus, S., published by John Wiley & Sons, in particular on pages 564 to 571. They comprise in particular:

depositing 19 a buffer layer 5 whose thickness is between 10 nm and 200 nm, 50 nm in this instance, based on cadmium sulphide CdS, zinc sulphide ZnS, indium sulphide In₂S₃ or others via chemical bath or vacuum deposition (sputtering, ALD, etc.)

depositing 19 a window layer 6 whose thickness is between 50 nm and 500 nm, 200 nm in this instance, via sputtering. It is generally a bilayer (ZnO/ZnO:Al, ZnO/ITO, etc.). Other deposition methods (chemical bath deposition (CBD) or ALD) or other materials are also possible (metal nanowires, SnO₂:F, etc.)

1. An arrangement for a thin-film photovoltaic cell stack comprising a substrate layer for a photovoltaic cell and a molybdenum grid positioned on the substrate layer, an ultra-thin light absorber layer covering the molybdenum grid and filling the holes in the molybdenum grid, and a buffer layer positioned on the ultra-thin light absorber layer and a window layer positioned on the buffer layer.

2. The arrangement according to claim 1, wherein the ultra-thin light absorber layer is an alloy of copper, indium, gallium and selenium.

3. The arrangement according to claim 1, wherein the ultra-thin light absorber layer is an alloy of copper, zinc, tin, and selenium and/or sulphur.

4. The arrangement according to claim 1, comprising a dielectric layer positioned between the substrate layer and the molybdenum grid.

5. The arrangement according to claim 4, comprising a reflective metal layer positioned between the substrate layer and the dielectric layer.

6. The method for fabricating an arrangement for a thin-film photovoltaic cell stack comprising the steps of:
providing a substrate for a photovoltaic cell;
depositing a carpet of microspheres on said substrate;
depositing molybdenum on the carpet of microspheres, a portion of which slips into the interstices separating the microspheres;
removing the microspheres to leave a molybdenum grid;
depositing an ultra-thin light absorber layer on the molybdenum grid; and
depositing a buffer layer and a window layer on the ultra-thin light absorber layer.

7. The method according to claim 6, comprising, in addition, a step of processing the microspheres, after their deposition and before the molybdenum deposition step, modifying the geometry of the microspheres.

8. The method according to claim 7, wherein the step of processing the microspheres comprises an etching operation and/or an annealing operation.

9. The method according to claim 6, comprising, in addition, a step of depositing a dielectric layer on the substrate before the deposition of the microspheres; the dielectric layer then being located between the substrate and the carpet of microspheres.

10. The method according to claim 9, comprising, in addition, a step of depositing a reflective metal, before the deposition of the dielectric layer, the reflective metal layer then being positioned between the substrate layer and the dielectric layer.

11. The method according to claim 6, wherein the deposition of the molybdenum layer on the microspheres is carried out at a thickness of between 100 and 2000 nm.

12. The method according to claim 11, wherein the deposition of the molybdenum layer on the microspheres is carried out at a thickness of substantially 500 nm.

13. The method according to claim 6, wherein the deposition of the dielectric layer is based on titanium dioxide TiO₂ or alumina Al₂O₃.

14. The method according to claim 6, wherein the deposition of the carpet of microspheres implements microspheres of between 100 nm and 5 μm in diameter.

15. The method according to claim 14, wherein the deposition of the carpet of microspheres implements microspheres of substantially 1 μm in diameter.

16. The method according to claim 6, wherein the removal of the microspheres implements an ultrasound waterbath.
